(19) United States
(12) Patent Application Publication
(10) Pub. No.: US 2026/0190445 A1
(43) Pub. Date: Jul. 2, 2026

(54) BACKSIDE FIN ISOLATION STRUCTURES BETWEEN SEMICONDUCTOR DEVICES

(71) Applicant: Intel Corporation, Santa Clara, CA (US)

(72) Inventors: Shaun Mills, Hillsboro, OR (US); Mauro J. Kobrinsky, Portland, OR (US); Joseph D'Silva, Hillsboro, OR (US); Ehren Mannebach, Beaverton, OR (US); Jonathan Ludwig, Portland, OR (US)

(73) Assignee: Intel Corporation, Santa Clara, CA (US)

(21) Appl. No.: 19/002,919

(22) Filed: Dec. 27, 2024

(51) Int. Cl. H10D 84/01; H01L 21/762; H10D 84/83

(52) U.S. Cl. CPC H10D 84/0153; H10D 84/832; H10W 10/014; H10W 10/17

(57) ABSTRACT

Techniques to form an integrated circuit having fin isolation structures that are formed from the backside of the structure. FETs (field effect transistors) each includes semiconductor material extending in a first direction between source and drain regions, and gate structures extending in a second direction around the semiconductor material of each FET. A fin isolation structure may extend along the second direction between the FETs to provide electrical isolation between the FETs. The fin isolation structure may include one or more dielectric materials that are deposited within a trench that is formed from the backside of the structure. In an example, an etch stop layer is present over the semiconductor devices, and the backside fin isolation structure may contact an underside of the etch stop layer. The fin isolation structure may exhibit an inverse tapering profile compared to etched features formed on the frontside.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Maintaining a certain level of quality among the various transistor elements can be a challenge due to the number of different fabrication processes they may be subjected to. Accordingly, there remain a number of non-trivial challenges with respect to forming such high-density semiconductor devices.

### BRIEF DESCRIPTION OF THE DRAWINGS

FIG. 1 is a cross-sectional view of different semiconductor devices in an integrated circuit that are separated by a backside-formed fin isolation structure, in accordance with an embodiment of the present disclosure.

FIGS. 2A-2M are cross-sectional views that illustrate different stages in an example process for forming an integrated circuit configured with backside-formed fin isolation structure between semiconductor devices, in accordance with some embodiments of the present disclosure.

FIG. 3 illustrates a cross-sectional view of a chip package containing one or more semiconductor dies, in accordance with some embodiments of the present disclosure.

FIG. 4 is a flowchart of a fabrication process for semiconductor devices having a backside-formed fin isolation structure between them, in accordance with an embodiment of the present disclosure.

FIG. 5 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having fin isolation structures that are formed from the backside of the structure. The techniques can be used in any number of integrated circuit applications and are particularly useful with respect to logic and memory cells, such as those cells that use finFETs or gate-all-around transistors (e.g., ribbonFETs and nanowire FETs) or forksheet transistors. In one such example, FETs (field effect transistors) each includes semiconductor material extending in a first direction between source and drain regions, and gate structures extending in a second direction around the semiconductor material of each FET. The semiconductor material of each FET may be a fin or any number of nanowires (or nanoribbons or nanosheets, as the case may be). A fin isolation structure may extend along the second direction between the FETs to provide electrical isolation between the FETs. The fin isolation structure may include one or more dielectric materials that are deposited within a trench that is formed from the backside of the structure. According to some embodiments, an etch stop layer is present over the semiconductor devices and acts to limit the backside fin isolation structure from extending too far into the topside interconnect region, such that the fin isolation structure may contact an underside of the etch stop layer. Since the fin isolation structure is formed from the backside, it may exhibit an inverse tapering profile compared to etched features formed on the frontside. Accordingly, a first width along a top surface of the fin isolation structure may be narrower compared to a second width along a bottom surface of the fin isolation structure. Numerous variations and embodiments will be apparent in light of this disclosure.

### General Overview

As previously noted above, there remain a number of non-trivial challenges with respect to integrated circuit fabrication. In more detail, isolating semiconductor devices from one another is important to provide desired circuit and logic arrangements. Several different isolation structures and techniques are used to provide electrical isolation. One such structure is a fin isolation structure that electrically isolates different portions of a semiconductor fin. Since several devices can be formed along the length of a single fin, fin isolation structures can be used to isolate devices along the fin. The fin isolation structures may include dielectric material formed within a trench that cuts through a given fin and runs perpendicular to the length of the fin. However, the frontside etching process used to form trenches that are later filled with dielectric material can suffer from significant variation across a given die, which can require over etching in certain areas to ensure that the isolation structures extend through the entire height of the devices. The over etching can damage other topside semiconductor features, such as spacer structures, which leads to decreased device performance or inoperability.

Thus, and in accordance with an embodiment of the present disclosure, techniques are provided herein to form the fin isolation structures entirely from the backside of the substrate to avoid etching processes on the topside that may damage other transistor elements. In some embodiments, suitable lithography techniques are performed on the backside of the structure (e.g., following the removal of the substate from the backside) to form trench-like openings between semiconductor devices that extend upwards towards the topside interconnect region. The openings are filled with one or more dielectric materials to form the fin isolation structures. To prevent the fin isolation structure from extending too far upwards into the topside interconnect region, an etch stop layer may be provided over the semiconductor devices to halt the etching process of the trench-like openings from the backside, according to some embodiments. In such case, the fin isolation structure contacts the underside of the etch stop layer. Due to the backside formation of the fin isolation structures, they may exhibit a width that tapers from a bottom surface of the fin isolation structures to a top surface of the fin isolation structures. The top surface of the fin isolation structures may abut against the etch stop layer. In some embodiments, a seam is visible between the dielectric material formed within the trench-like recess of a given fin isolation structure, and the seam extends upwards from the bottom surface of the fin isolation structure without reaching the top surface of the fin isolation structure.

According to an embodiment, an integrated circuit includes a first semiconductor device having a first semiconductor region extending in a first direction from a first source or drain region and a first gate structure extending in a second direction over the first semiconductor region, a second semiconductor device having a second semiconductor region extending in the first direction from a second source or drain region and a second gate structure extending in the second direction over the second semiconductor region, and a dielectric structure extending in the second direction between the first source or drain region and the second source or drain region and extending in a third direction along an entire height of the first source or drain region and the second source or drain region. The second semiconductor region is aligned with the first semiconductor region along the first direction. The dielectric structure has a first width along the first direction across a top surface of the dielectric structure and a second width along the first direction across a bottom surface of the dielectric structure. The first width is less than the second width.

According to another embodiment, an integrated circuit includes a first semiconductor region extending in a first direction from a first source or drain region, a second semiconductor region extending in the first direction from a second source or drain region, a dielectric structure extending in a second direction between the first semiconductor region and the second semiconductor region and extending in a third direction along at least an entire height of the first source or drain region and the second source or drain region. The dielectric structure has tapered sidewalls such that a top surface of the dielectric structure has a first width along the first direction, and a bottom surface of the dielectric structure has a second width along the first direction with the first width being less than the second width. The second semiconductor region is aligned with the first semiconductor region along the first direction.

According to another embodiment, an electronic device includes a chip package having one or more dies. At least one of the one or more dies includes a first plurality of semiconductor nanoribbons extending in a first direction from a first source or drain region, a second plurality of semiconductor nanoribbons extending in the first direction from a second source or drain region with the second plurality of semiconductor nanoribbons being aligned with the first plurality of semiconductor nanoribbons along the first direction, a first gate structure extending in a second direction of the first plurality of semiconductor nanoribbons, a second gate structure extending in the second direction of the second plurality of semiconductor nanoribbons, and a dielectric structure extending in the second direction between the first source or drain region and the second source or drain region and extending in a third direction along at least an entire height of the first source or drain region and the second source or drain region. The dielectric structure has tapered sidewalls such that a top surface of the dielectric structure has a first width along the first direction and a bottom surface of the dielectric structure has a second width along the first direction with the first width being less than the second width.

According to an embodiment, a method of forming an integrated circuit includes forming a fin comprising semiconductor material, the fin extending above a substrate and extending lengthwise along a first direction; forming a first dielectric layer around a base portion of the fin; forming source or drain regions at the ends of the fin; forming a gate structure over the semiconductor material of the fin in a second direction different from the first direction; removing at least a portion of the substrate from a backside of the integrated circuit; etching a trench recess from the backside through at least an entire height of the gate structure; and filling the trench recess with a dielectric material.

The techniques can be used with any type of planar or non-planar transistors, including finFETs (sometimes called double-gate transistors, or tri-gate transistors), or nanowire and nanoribbon transistors (sometimes called gate-all-around transistors), or forksheet transistors, to name a few examples. The source and drain regions can be, for example, epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of one or more fin isolation structures (e.g., dielectric walls) between semiconductor devices and extending in the same lengthwise direction as the gate structures, that have tapered sidewalls. Due to the tapered sidewalls, a bottom surface of the fin isolation structures may be larger (e.g., at least 5 nm larger) compared to a top surface of the fin isolation structures. In some examples, the top surface of the fin isolation structures abut an etch stop layer, such as a dielectric layer of aluminum oxide, silicon carbide, or silicon nitride, to name a few examples. In some examples, such imaging tools may be used to observe the presence of a seam within a central portion of the fin isolation structures, where the seam extends from the bottom surface of the fin isolation structures towards the top surface of the fin isolation structures without reaching the top surface.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

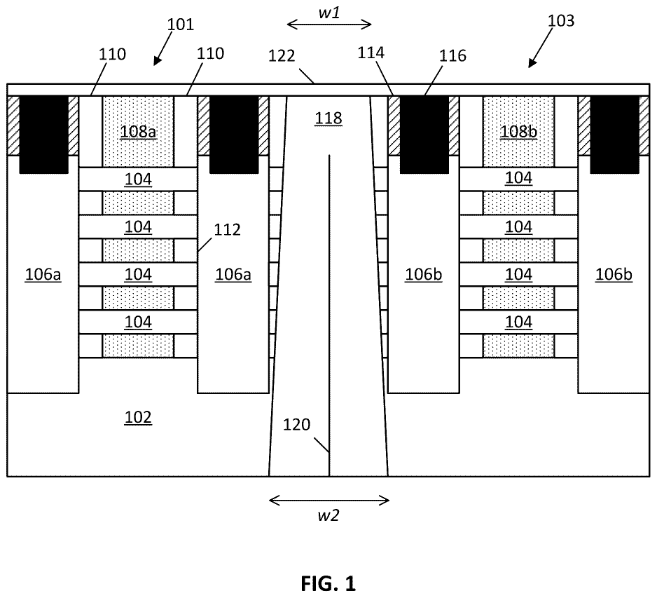

FIG. 1 is a cross-section view taken through semiconductor devices 101 and 103 along a ‘fin’ direction that illustrates the semiconductor bodies extending between source or drain regions of each of the semiconductor devices, in accordance with an embodiment of the present disclosure. Each of the semiconductor devices may be, for instance, non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons, nanowires, or nanosheets that extend between source and drain regions). Other examples may have a forksheet structure having a p-type device and an n-type device separated by a dielectric spine or structure. According to some embodiments, semiconductor devices 101 are p-channel devices (e.g., PMOS) and semiconductor devices 103 are n-channel devices (e.g., NMOS), or vice versa.

The semiconductor material used in each of the semiconductor devices may be formed from or on a semiconductor substrate. According to some embodiments, the substrate is removed following the completion of all topside processing and is replaced with a base dielectric structure 102. Base dielectric structure 102 may represent any number of dielectric layers and/or materials. In some examples, base dielectric structure 102 includes one or more layers of silicon dioxide.

The one or more semiconductor regions of the devices may include fins that can be, for example, native to the substrate (formed from the substrate itself), such as silicon fins etched from a bulk silicon substrate. Alternatively, the fins can be formed of material deposited onto the substrate. In one such example case, a blanket layer of SiGe can be deposited onto a silicon substrate, and then patterned and etched to form a plurality of SiGe fins extending from that substrate. In still other embodiments, the fins include alternating layers of material (e.g., alternating layers of silicon and SiGe) that facilitates forming of nanowires and nanoribbons and nanosheets during a gate forming process where one type of the alternating layers is selectively etched away so as to liberate the other type of alternating layers within the channel region, so that a gate-all-around process or a forksheet gate process can then be carried out. Again, the alternating layers can be blanket deposited and then etched into fins or deposited into fin-shaped trenches, in some examples.

Semiconductor devices 101 and 103 include one or more semiconductor regions (also called channel regions), such as one or more nanoribbons 104 extending between epitaxial source or drain regions 106a/106b in the first direction. A first gate structure 108 a extends over nanoribbons 104 of semiconductor device 101 in a second direction (e.g., into and out of the page) to form the transistor gate of semiconductor device 101 and second gate structure 108b extends over nanoribbons 104 of semiconductor device 103 in the second direction to form the transistor gate of semiconductor device 103.

Any of source or drain regions 106a/106b may act as either a source region or a drain region, depending on the application and dopant profile. Any semiconductor materials suitable for source and drain regions can be used (e.g., group IV and group III-V semiconductor materials) for any of the illustrated source or drains regions 106a/106b. In any such cases, the composition and doping of source or drain regions 106a and 106b may be the same or different, depending on the polarity of the transistors. In an example, semiconductor device 101 is a p-channel device having a high concentration of p-type dopants in the associated source or drain regions 106a, and semiconductor device 103 is an n-channel device having a high concentration of n-type dopants in the associated source or drain regions 106b. Example p-type dopants include boron and example n-type dopants include phosphorous or arsenic. Any number of source and drain configurations and materials can be used. In some examples, source or drain regions 106b include silicon germanium doped with boron and source or drain regions 106a include silicon doped with phosphorous.

The gate structures 108a/108b may each include a gate electrode that is made up of a conductive fill and one or more metal workfunction layers, according to some embodiments. The gate structures 108a/108b also include a gate dielectric that may represent any number of dielectric layers. The conductive fill may include any sufficiently conductive material such as a metal, metal alloy, or doped polysilicon. In some examples, the conductive fill includes tungsten (W), although other metals or conductive materials may be used, such as aluminum (Al), molybdenum (Mo), ruthenium (Ru), cobalt (Co), or doped polysilicon. In some embodiments, semiconductor device 101 is a p-channel device having a gate structure 108a with one or more workfunction layers of molybdenum nitride (MoN). Other metal workfunction layers of p-channel devices can include tantalum nitride (TaN) or tungsten. In some embodiments, semiconductor device 103 is an n-channel device having a gate structure 108b with one or more workfunction layers of titanium aluminum carbide. Other metal workfunction layers of n-channel devices can include tantalum nitride (TaN).

The gate dielectric of each gate structure 108a/108b may include any suitable gate dielectric material(s). In some embodiments, the gate dielectric includes a layer of native oxide material (e.g., silicon dioxide germanium dioxide, or SiGe oxide) on nanoribbons 104, and a layer of high-k dielectric material (e.g., hafnium oxide or aluminum oxide) on the native oxide. According to some embodiments, spacer structures 110 and inner spacers 112 are present along the sidewalls of gate structures 108a/108b. Spacer structures 110 and inner spacers 112 may be any suitable dielectric material, such as silicon nitride, and provide separation between a given gate structure 108a/108b and the adjacent source or drain region 106a/106b. Inner spacers 112 may separate adjacent nanoribbons 104 from one another along a third direction (e.g., a vertical direction).

According to some embodiments, a dielectric fill 114 may be present over the source or drain regions 106a/106b within the corresponding source/drain trenches of semiconductor devices 101 and 103. A top surface of dielectric fill 114 may be substantially co-planar with a top surface of spacer structures 110. Dielectric fill 114 may include any suitable dielectric material, such as silicon dioxide, in some examples.

According to some embodiments, conductive contacts 116 are provided through dielectric fill 114 and contacting a top portion of source or drain regions 106a/106b. Conductive contacts 116 can include any suitable conductive material, such as tungsten, molybdenum, ruthenium, cobalt, or other metals. Conductive contacts 116 may be formed during the same metal deposition process(es) such that they all include the same conductive material.

According to some embodiments, semiconductor device 101 is electrically isolated from semiconductor device 103 along the first direction by a fin isolation structure 118 that extends along the second direction between semiconductor devices 101 and 103. According to some embodiments, fin isolation structure 118 is formed entirely from the backside of the integrated circuit. In some examples, a bottom surface of fin isolation structure 118 is substantially coplanar with a bottom surface of base dielectric structure 102, and a top surface of fin isolation structure 118 is substantially coplanar with a top surface of spacer structures 110. According to some embodiments, the backside processing of fin isolation structure 118 results in a tapered sidewall profile having a first width w1 along a top surface of fin isolation structure 118 and a second width w2 along a bottom surface of fin isolation structure 118 with the second width w2 being greater than the first width w1. For example, second width w2 may be at least 3 nm, at least 5 nm, at least 7 nm, or at least 10 nm greater than first width w1.

A conformal deposition process, such as chemical vapor deposition (CVD) or atomic layer deposition (ALD) may be used to form dielectric material within a backside-formed recess to create fin isolation structure 118. In some examples, the dielectric material of fin isolation structure 118 includes a low-k dielectric material, such as silicon dioxide or generally any dielectric material having a dielectric constant of less than 4.0. Other dielectric materials may be used as well, including those with higher dielectric constants, such as silicon nitride. In some examples, fin isolation structure 118 includes a dielectric liner having a high-k dielectric material (e.g., having a dielectric constant greater than about 4.0) with a dielectric fill having a low-k dielectric material. According to some embodiments, a seam 120 may be present within fin isolation structure 118 due to the conformal deposition process where the dielectric material contacts itself as it forms inward from the trench surfaces. Since fin isolation structure 118 is formed from the backside, seam 120 extends from the bottom surface of fin isolation structure 118 upwards towards the top surface of fin isolation structure 118 without actually reaching the top surface of fin isolation structure 118.

According to some embodiments, an etch stop layer 122 is present along a top surface of the semiconductor devices, such as on a top surface of spacer structures 110. Etch stop layer 122 may include any suitable dielectric material that can halt or slow the reactive ion etching (RIE) process performed from the backside. In some examples, etch stop layer 122 includes aluminum oxide, silicon carbide, or silicon nitride. According to some embodiments, the top surface of fin isolation structure 118 abuts against an underside of etch stop layer 122.

### Fabrication Methodology

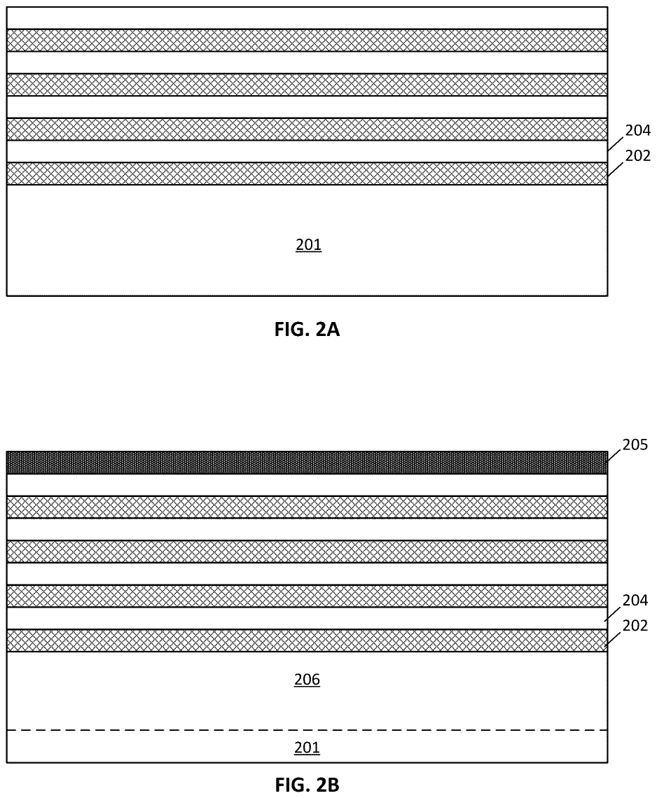

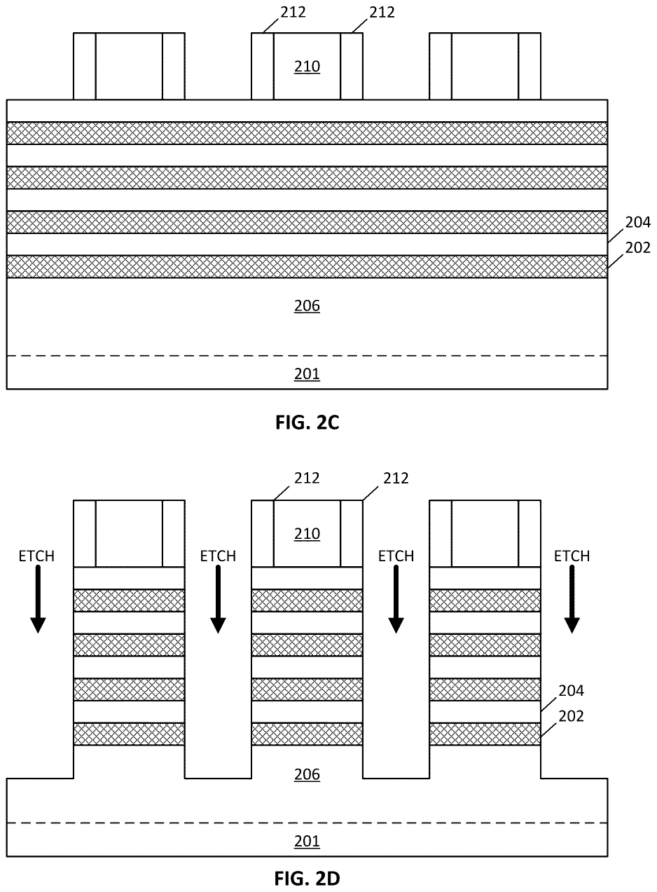

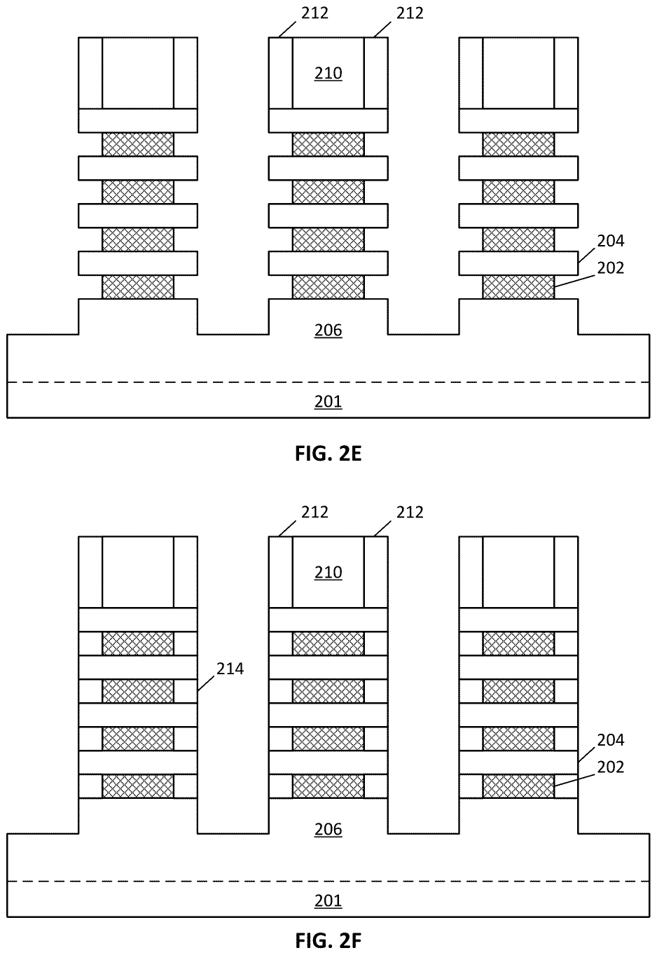

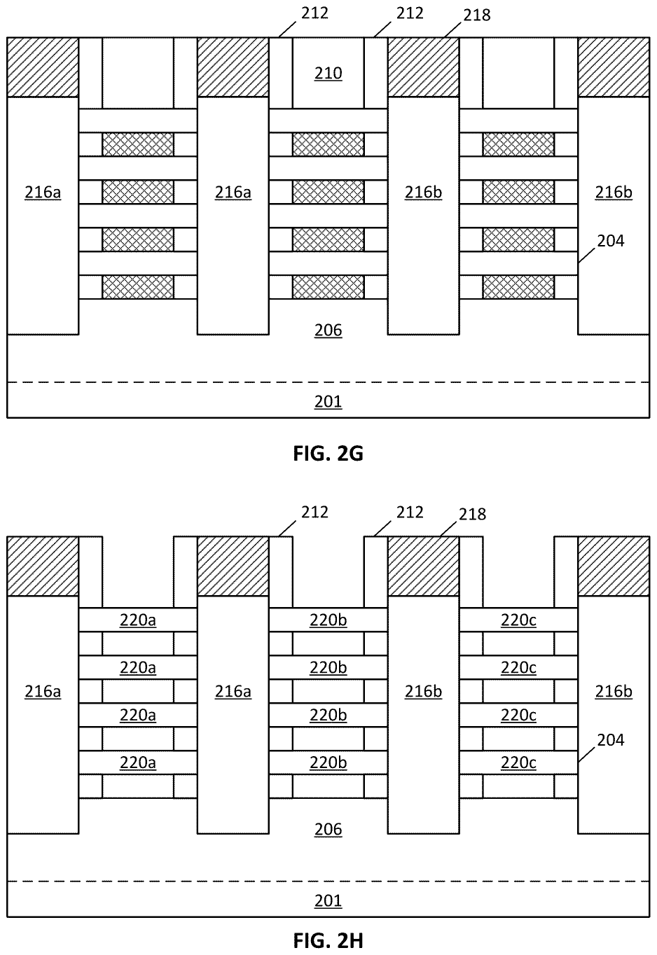

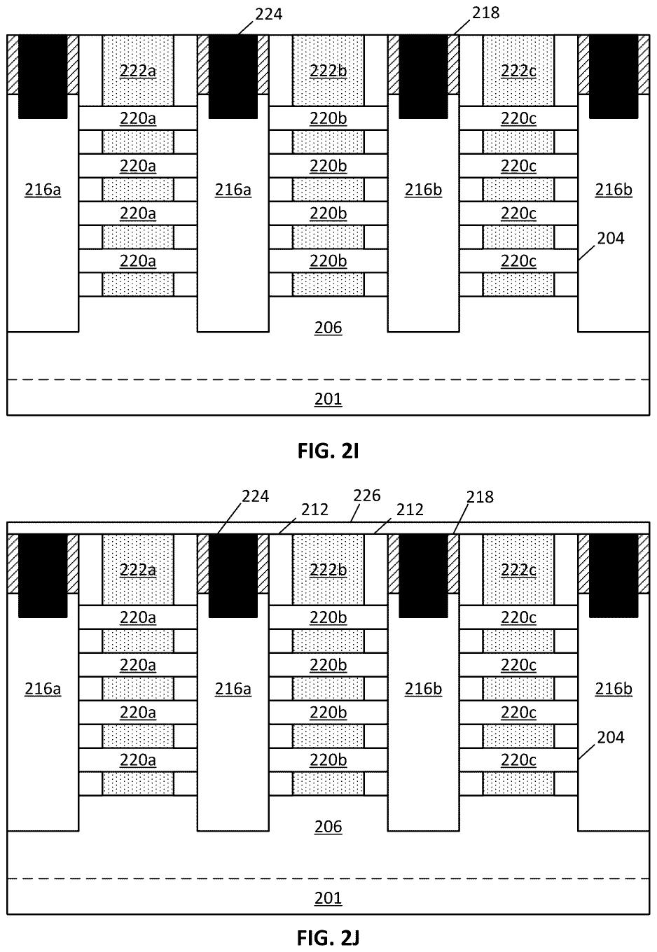

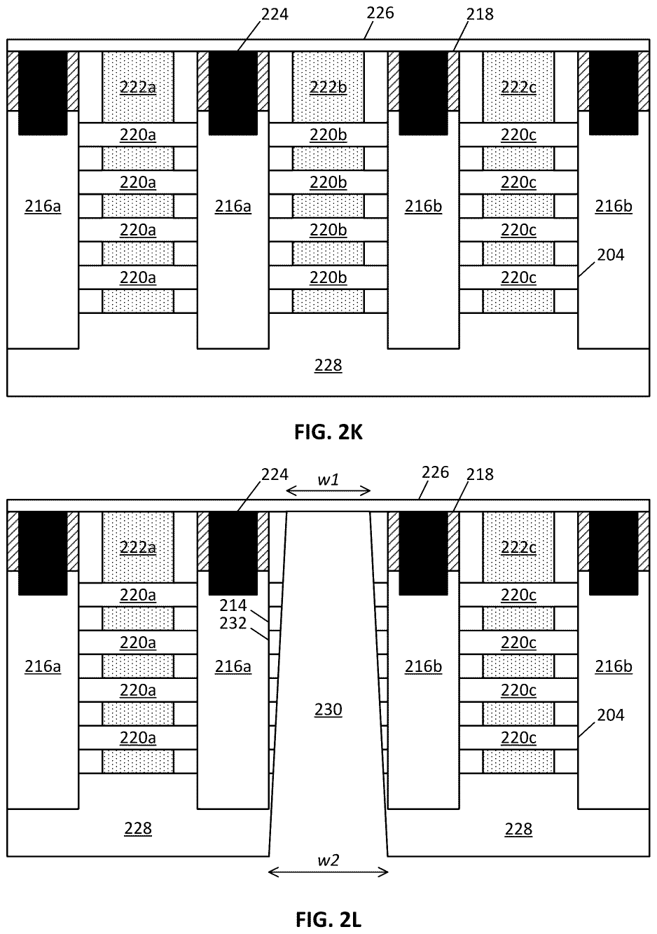

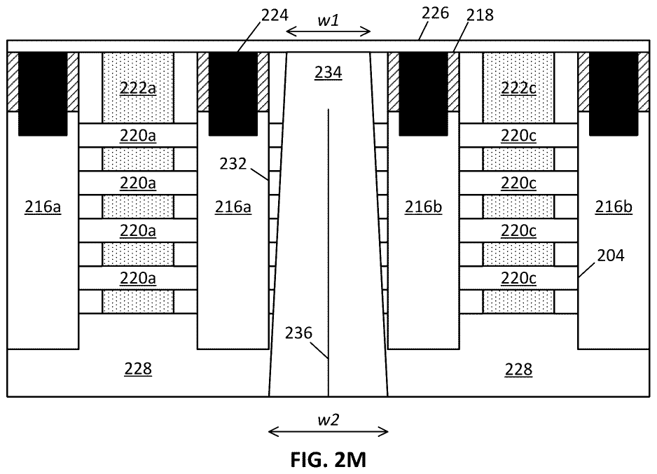

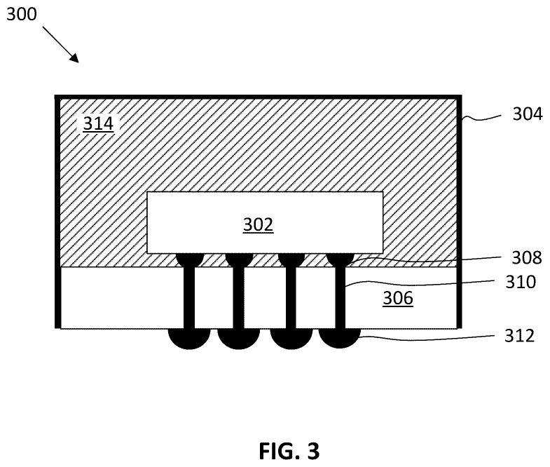

FIGS. 2A-2M include cross-sectional views that collectively illustrate an example process for forming an integrated circuit configured with a backside-formed fin isolation structure, in accordance with an embodiment of the present disclosure. FIGS. 2A-2M represent a similar cross-sectional view as that of FIG. 1 across a series of semiconductor devices. The depicted structure evolves as the process flow continues, culminating in the structure shown in FIG. 2M, which is similar to the structure shown in FIG. 1. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but other materials and process parameters may be used as well, as will be appreciated in light of this disclosure. Although only one fin isolation structure is depicted, it should be understood that the same process described herein could be used to form any number of similar fin isolation structures across a given die.

FIG. 2A illustrates a cross-sectional view taken through a substrate 201 having a series of material layers formed over substrate 201, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or SiGe), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 include a semiconductor material suitable for use as a nanoribbon such as silicon (Si), SiGe, germanium, or III-V materials like indium phosphide (InP) or gallium arsenide (GaAs). Sacrificial layers 202 include a material that can be selectively removed relative to semiconductor layers 204. In some examples, for instance, semiconductor layers 204 are silicon and sacrificial layers 202 are SiGe, or vice-versa. In some other examples where SiGe is used in each of semiconductor layers 204 and in sacrificial layers 202, the germanium concentration is different between semiconductor layers 204 and sacrificial layers 202, so as to allow for etch selectivity. For example, semiconductor layers 204 may include a higher germanium content compared to sacrificial layers 202.

While dimensions can vary from one example embodiment to the next, the thickness of each semiconductor layer 204 may be between about 5 nm and about 20 nm, in some examples. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any material deposition technique, such as chemical vapor deposition (CVD), plasma-enhanced chemical vapor deposition (PECVD), physical vapor deposition (PVD), or atomic layer deposition (ALD), or epitaxial growth.

FIG. 2B depicts a cross-section view of the structure shown in FIG. 2A following the formation of a cap layer 205 and the subsequent formation of fins beneath cap layer 205, according to an embodiment. Cap layer 205 may be any suitable hard mask material such as a carbon hard mask (CHM) or silicon nitride. Cap layer 205 is patterned into rows to form corresponding rows of fins from the alternating layer stack of sacrificial layers 202 and semiconductor layers 204. Cap layer 205 extends along the top of each fin in a first direction.

According to some embodiments, an anisotropic etching process through the layer stack continues into at least a portion of substrate 201. Portions of substrate 201 beneath the fins are not etched and yield subfin regions 206. The etched portions of substrate 201 that are not under the fins may be filled with a dielectric fill that acts as shallow trench isolation (STI) between adjacent fins. The dielectric fill is not shown in these cross-sections as it extends in the first direction along the sides of subfin regions 206 that are into and out of the page. The dielectric fill may be any suitable dielectric material such as silicon dioxide. The subfin regions 206 represent remaining portions of substrate 201 flanked by the dielectric fill, according to some embodiments.

FIG. 2C depicts a cross-section view of the structure shown in FIG. 2B following the formation of sacrificial gates 210 and spacer structures 212, according to some embodiments. A gate masking layer may first be patterned in strips that extend orthogonally across each of the fins (e.g., in a second direction) in order to form corresponding sacrificial gates 210 in strips beneath the gate masking layers. Afterwards, the gate masking layers may be removed or may remain as a cap layer above each sacrificial gate 210. According to some embodiments, the sacrificial gate material is removed in all areas not protected by the gate masking layers. Sacrificial gate 210 may be any suitable material that can be selectively removed without damaging the semiconductor material of the fins. In some examples, sacrificial gate 210 includes polysilicon.

According to some embodiments, spacer structures 212 are formed along the sidewalls of sacrificial gates 210. Spacer structures 212 may be conformally deposited (e.g., CVD or ALD)_and then etched back or otherwise removed (e.g., via anisotropic or directional etch) from horizontal surfaces, such that spacer structures 212 remain mostly only on sidewalls of any exposed structures. The width of spacer structures 212 (along the first direction) may vary from one example to the next, but in some cases is in the range of 3 nm to 20 nm. According to some embodiments, spacer structures 212 may be any suitable dielectric material, such as silicon nitride, silicon carbon nitride, or silicon oxycarbonitride. In one such embodiment, spacer structures 212 comprise a nitride and the dielectric fill adjacent to subfin regions 206 comprises an oxide, so as to provide a degree of etch selectivity during final gate processing.

FIG. 2D depicts a cross-section view of the structure shown in FIG. 2C following the removal of exposed portions of the fins not protected by sacrificial gates 210 and spacer structures 212, according to some embodiments. The exposed fin portions may be removed using any anisotropic etching process, such as RIE or other directional etch process. The removal of the exposed fin portions creates source or drain trenches that alternate with gate trenches (currently filled with sacrificial gates 210) along the first direction, according to some embodiments. In some embodiments, at least a portion of subfin regions 206 is also removed such that a top surface of subfin regions 206 is recessed below a top surface of the adjacent dielectric fill. The recessed area above may be filled with one or more dielectric materials.

FIG. 2E depicts a cross-section view of the structure shown in FIG. 2D following the removal of portions of sacrificial layers 202, according to an embodiment of the present disclosure. An isotropic etching process may be used to selectively recess the exposed ends of each sacrificial layer 202 (e.g., while etching comparatively little of semiconductor layers 204).

FIG. 2F depicts a cross-section view of the structure shown in FIG. 2E following the formation of internal spacers 214, according to an embodiment of the present disclosure. Internal spacers 214 may have a material composition that is similar to or the exact same as spacer structures 212. Accordingly, internal spacers 214 may be any suitable dielectric material that exhibits high etch selectively to semiconductor materials such as silicon and/or silicon germanium. Internal spacers 214 may be, for example, conformally deposited over the sides of the fin structure using a conformal deposition process like CVD or ALD and then etched back using an isotropic etching process to expose the ends of semiconductor layers 204. According to some embodiments, internal spacers 214 have a similar width (e.g., along the first direction) to spacer structures 212. A portion of the dielectric material used for form internal spacers 214 may remain at the bottom of the source/gate trenches.

FIG. 2G depicts a cross-section view of the structure shown in FIG. 2F following the formation of first source or drain regions 216a and second source or drain regions 216b within the source/drain trenches, according to some embodiments. Source or drain regions 216a/216b may be formed in the areas that had been previously occupied by the exposed fins between spacer structures 212. According to some embodiments, source or drain regions 216a/216b are epitaxially grown from the exposed semiconductor material at the ends of semiconductor layers 204. In some example embodiments, first source or drain regions 216a are p-channel source or drain regions (e.g., epitaxial silicon germanium with p-type dopants) and second source or drain regions 216b are n-channel source or drain regions (e.g., epitaxial silicon with n-type dopants).

According to some embodiments, a dielectric fill 218 is provided over source or drain regions 216a/216b. In some examples, dielectric fill 218 occupies a remaining volume within the source/drain trenches around and over portions of source or drain regions 216a/216b. Dielectric fill 218 may be any suitable dielectric material, such as silicon dioxide. In some examples, dielectric fill 218 extends up to and planar with a top surface of spacer structures 212 (e.g., following a polishing procedure).

FIG. 2H depicts a cross-section view of the structure shown in FIG. 2G following the removal of sacrificial gates 210 and sacrificial layers 202, according to some embodiments. In examples where gate masking layers are still present, they may be removed at this time. Once sacrificial gates 210 are removed, the remaining fin portions extending between spacer structures 212 are exposed.

In the example where the fins include alternating sacrificial layers 202 and semiconductor layers 204, sacrificial layers 202 are selectively removed to leave behind nanoribbons 220a extending between first source or drain regions 216a, nanoribbons 220b extending between a first source or drain region 216a and a second source or drain region 216b, and nanoribbons 220c extending between second source or drain regions 216b. Each vertical set of nanoribbons represents the semiconductor region (also called channel region) of a different semiconductor device. Note that nanoribbons 220b are part of a “dummy” device that is not operational and are removed during a later process to form the backside fin isolation structure. It should be understood that any of nanoribbons 220a/220b/220c may also be nanowires or nanosheets. Sacrificial gates 210 and sacrificial layers 202 may be removed using the same isotropic etching process or different isotropic etching processes.

FIG. 2I depicts a cross-section view of the structure shown in FIG. 2H following the formation of a first gate structure 222a around the suspended nanoribbons 220a, a second gate structure 222b around suspended nanoribbons 220b, and a third gate structure 222c around the suspended nanoribbons 220c, according to an embodiment of the present disclosure. As noted above, each gate structure includes a gate dielectric and a gate electrode.

The gate dielectric may be conformally deposited around the nanoribbons using any suitable deposition process, such as ALD. The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric may include one or more silicates (e.g., titanium silicate, tungsten silicate, niobium silicate, and silicates of other transition metals). The gate dielectric may be a multilayer structure, in some examples. For instance, the gate dielectric may include a first layer on the nanoribbons, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-k material can be nitridized to improve its aging resistance.

The gate electrode may be deposited over the gate dielectric and can be any standard or proprietary conductive material that may include any number of gate cuts. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, one or more workfunction layers, resistance-reducing layers, and/or barrier layers. In an example, first gate structure 222a includes p-type workfunction materials such as, for example, tungsten. In an example, third gate structure 222c includes n-type workfunction materials such as titanium nitride or titanium aluminum carbide.

According to some embodiments, source/drain contacts 224 may be formed through dielectric fill 218 to contact the top surfaces of source or drain regions 216a/216b. Contacts 224 may include any suitable conductive material, such as tungsten, cobalt, molybdenum, or ruthenium, for making electrical contact with the underlying source or drain regions 216a/216b.

FIG. 2J depicts a cross-section view of the structure shown in FIG. 2I following the formation of an etch stop layer 226, according to some embodiments. Etch stop layer 226 may be any suitable dielectric material, such as aluminum oxide, silicon carbide, or silicon nitride, to name a few examples. Etch stop layer 226 may be formed directly on the top surface of spacer structures 212. In some examples, etch stop layer 226 is formed directly on the top surface of gate structures 222a/222b/222c (or on a top surface of a gate cap layer that is on the gate structures). In some examples, etch stop layer 226 is also formed on a top surface of source/drain contacts 224. In other examples, etch stop layer 226 is formed on a top surface of dielectric fill 218 and source/drain contacts 224 are later formed through etch stop layer 226 to reach source or drain regions 216a/216b.

Although not illustrated, any number of frontside interconnect layers may be formed over etch stop layer 226. The interconnect layers include dielectric layers, conductive vias, and conductive layers to carry power and/or signals to various transistor elements.

FIG. 2K depicts a cross-section view of the structure shown in FIG. 2J following the removal of substrate 201 and subsequent formation of a base dielectric structure 228, according to some embodiments. Any number of polishing, grinding, or etching processes may be used to remove the bulk portion of substrate 201. According to some embodiments, substrate 201 is removed until a bottom surface of subfin regions 206 (and a bottom surface of the dielectric fill adjacent to subfin regions 206) are exposed. The backside exposed subfin regions 206 may then be etched away using any suitable isotropic etching process and replaced with one or more backside dielectric layers that, along with the dielectric fill previously adjacent to the subfin regions 206, collectively represent at least a portion of base dielectric structure 228. Base dielectric structure 228 may include any suitable dielectric material, such as silicon dioxide or silicon oxynitride.

FIG. 2L depicts a cross-section view of the structure shown in FIG. 2K following the formation of a backside trench recess 230, according to some embodiments. Trench recess 230 extends along the second direction between two semiconductor devices and extends in a third direction (e.g., vertically or along the height of the devices) through nanoribbons 220b and the corresponding gate structure 222b. Trench recess 230 may effectively sever any conductive or semiconductive connection between first source or drain region 216a and second source or drain region 216b. According to some embodiments, trench recess 230 may be formed by etching through the noted materials using any number of suitable anisotropic etching processes, such as RIE. Trench recess 230 extends along at least an entire height of the adjacent source or drain regions 216a/216b. According to some embodiments, the etch process stops or substantially slows upon reaching etch stop layer 226, such that etch stop layer 226 is exposed at the top surface of trench recess 230.

According to some embodiments, trench recess 230 has a tapering width along the first direction that is narrowest at the top (w1) and widest at the bottom (w2). In some examples, width w2 is at least 3 nm, at least 5 nm, at least 7 nm, or at least 10 nm greater than the width w1.

According to some embodiments, portions of nanoribbons 220b may remain between inner spacers 214 as additional semiconductor regions 232. In some embodiments, these semiconductor regions 232 extend along the first direction from source or drain regions 216a/216b to the tapering sidewalls of trench recess 230, such that the ends of semiconductor regions 232 are exposed along the sidewalls of trench recess 230.

FIG. 2M depicts a cross-section view of the structure shown in FIG. 2L following the formation of a fin isolation structure 234 within trench recess 230, according to some embodiments. One or more dielectric materials may be deposited into trench recess 230 to form fin isolation structure 234. In some examples, fin isolation structure 234 includes any suitable low-k dielectric material, such as silicon dioxide.

According to some embodiments, the dielectric material of fin isolation structure 234 is deposited using a conformal deposition technique. As such, a seam 236 may be present within a central region of fin isolation structure 234. Since fin isolation structure 234 is formed from the backside, seam 236 extends from the bottom surface of fin isolation structure 234 towards the top surface of fin isolation structure 234 without reaching the top surface, according to some embodiments. Fin isolation structure 234 exhibits the same tapered shape as trench recess 230, and thus has a top surface with the first width w1 and a bottom surface with the second width w2. The top surface of fin isolation structure 234 may abut against etch stop layer 226. The additional semiconductor regions 232 may be left behind extending along the first direction between source or drain regions 216a/216b and fin isolation structure 234.

FIG. 3 illustrates an example embodiment of a chip package 300, in accordance with an embodiment of the present disclosure. As can be seen, chip package 300 includes one or more dies 302. One or more dies 302 may include at least one integrated circuit having semiconductor devices, such as any of the semiconductor devices disclosed herein. One or more dies 302 may include any other circuitry used to interface with other devices formed on the dies, or other devices connected to chip package 300, in some example configurations.

As can be further seen, chip package 300 includes a housing 304 that is bonded to a package substrate 306. The housing 304 may be any standard or proprietary housing, and may provide, for example, electromagnetic shielding and environmental protection for the components of chip package 300. The one or more dies 302 may be conductively coupled to a package substrate 306 using connections 308, which may be implemented with any number of standard or proprietary connection mechanisms, such as solder bumps, ball grid array (BGA), pins, or wire bonds, to name a few examples. Package substrate 306 may be any standard or proprietary package substrate, but in some cases includes a dielectric material having conductive pathways (e.g., including conductive vias and lines) extending through the dielectric material between the faces of package substrate 306, or between different locations on each face. In some embodiments, package substrate 306 may have a thickness less than 1 millimeter (e.g., between 0.1 millimeters and 0.5 millimeters), although any number of package geometries can be used. Additional conductive contacts 312 may be disposed at an opposite face of package substrate 306 for conductively contacting, for instance, a printed circuit board (PCB). One or more vias 310 extend through a thickness of package substrate 306 to provide conductive pathways between one or more of connections 308 to one or more of contacts 312. Vias 310 are illustrated as single straight columns through package substrate 306 for ease of illustration, although other configurations can be used (e.g., damascene, dual damascene, through-silicon via, or an interconnect structure that meanders through the thickness of substrate 306 to contact one or more intermediate locations therein). In still other embodiments, vias 310 are fabricated by multiple smaller stacked vias, or are staggered at different locations across package substrate 306. In the illustrated embodiment, contacts 312 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 312, to inhibit shorting.

In some embodiments, a mold material 314 may be disposed around the one or more dies 302 included within housing 304 (e.g., between dies 302 and package substrate 306 as an underfill material, as well as between dies 302 and housing 304 as an overfill material). Although the dimensions and qualities of the mold material 314 can vary from one embodiment to the next, in some embodiments, a thickness of mold material 314 is less than 1 millimeter. Example materials that may be used for mold material 314 include epoxy mold materials, as suitable. In some cases, the mold material 314 is thermally conductive, in addition to being electrically insulating.

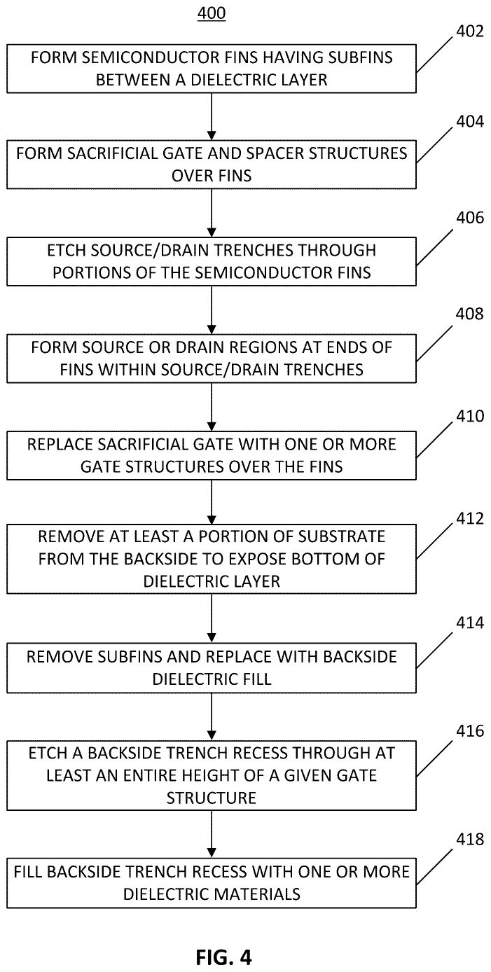

FIG. 4 is a flow chart of a method 400 for forming at least a portion of an integrated circuit, according to an embodiment. Various operations of method 400 may be illustrated in FIGS. 2A-2M . However, the correlation of the various operations of method 400 to the specific components illustrated in the aforementioned figures is not intended to imply any structural and/or use limitations. Rather, the aforementioned figures provide one example embodiment of method 400. Other operations may be performed before, during, or after any of the operations of method 400. For example, method 400 does not explicitly describe various standard processes that are usually performed to form transistor structures. Some of the operations of method 400 may be performed in a different order than the illustrated order.

Method 400 begins with operation 402 where a plurality of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of SiGe can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches, according to some examples. The fins may also include a cap structure over each fin that is used to define the locations of the fins during, for example, an RIE process. The cap structure may be a dielectric material, such as silicon nitride.

According to some embodiments, a dielectric layer is formed around subfin portions of the one or more fins. In some embodiments, the dielectric layer extends between each pair of adjacent parallel fins and runs lengthwise in the same direction as the fins. In some embodiments, the anisotropic etching process that forms the fins also etches into a portion of the substrate and the dielectric layer may be formed within the recessed portions of the substrate. Accordingly, the dielectric layer acts as shallow trench isolation (STI) between adjacent fins. The dielectric layer may be any suitable dielectric material, such as silicon dioxide. Lower portions of the fins adjacent to the dielectric layer may be identified as the subfins.

Method 400 continues with operation 404 where sacrificial gates are formed over the fins. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 400 continues with operation 406 where exposed portions of the fins are removed to form source/drain trenches. Any exposed portions of the fins not covered by the sacrificial gates or spacer structures may be removed using any anisotropic etching process, such as reactive ion etching (RIE). Sacrificial layers of the fins may be recessed (e.g., via isotropic etch process) followed by deposition of internal spacers (e.g., silicon nitride), as described above.

Method 400 continues with operation 408 where source or drain regions are formed at opposite ends of the fins within the source/drain trenches. The source or drain regions may be formed in the areas that had been previously occupied by the exposed fins between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon with n-type dopants) or PMOS source or drain regions (e.g., epitaxial SiGe with p-type dopants). A dielectric fill may be formed between and over the source or drain regions along a given source/drain trench. The dielectric fill may be any suitable dielectric material, such as silicon dioxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth.

Method 400 continues with operation 410 where the sacrificial gate is replaced with one or more gate structures. The sacrificial gate may be removed using an isotropic etching process that selectively removes all of the material from the sacrificial gate, thus exposing the various fins between the set of spacer structures. According to some embodiments, any sacrificial layers within the exposed fins between the spacer structures may also be removed to release nanoribbons or nanosheets (e.g., directly adjacent to the first sacrificial material) of semiconductor material.

The one or more gate structures may include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any number of conductive material layers, such as any metals, metal alloys, or polysilicon. The gate electrode may be deposited using electroplating, electroless plating, CVD, ALD, PECVD, or PVD, to name a few examples.

Method 400 continues with operation 412 where at least a portion of the substrate is removed from the backside to expose a bottom surface of the subfin regions and the dielectric layer adjacent to the subfin regions. Any number of polishing, grinding, or etching processes may be used to remove the bulk portion of the substrate beneath the semiconductor devices.

Method 400 continues with operation 414 where the exposed subfin regions are removed and replaced with a backside dielectric fill. The backside exposed subfin regions may be etched away using any suitable isotropic etching process that removes the exposed semiconductor material of the subfin regions. The cavities left behind by the removal of the subfin regions may be filled with a dielectric fill (or any number of dielectric layers) that, along with the dielectric layer previously adjacent to the subfin regions, collectively represent at least a portion of a base dielectric structure beneath the semiconductor devices. The base dielectric structure may include any suitable dielectric material, such as silicon dioxide or silicon oxynitride.

Method 400 continues with operation 416 where a backside trench recess is etched through the at least a portion of the base dielectric structure and through at least an entire height of a given gate structure. According to some embodiments, the trench recess extends along the second direction between two semiconductor devices and extends in a third direction (e.g., vertically or along the height of the devices) through the nanoribbons and the corresponding gate structure of the semiconductor device previously between the two semiconductor devices. The trench recess may effectively sever any conductive or semiconductive connection between the source or drain regions of the two semiconductor devices. According to some embodiments, the trench recess may be formed by etching through the base dielectric structure, metal gate materials, gate dielectric layers, and semiconductor nanoribbons using any number of suitable anisotropic etching processes, such as RIE. In some examples, the trench recess extends along at least an entire height of adjacent source or drain regions from the two semiconductor devices. According to some embodiments, the etch process stops or substantially slows upon reaching an etch stop layer formed over the semiconductor devices.

Method 400 continues with operation 418 where the backside trench recess is filled with one or more dielectric materials to form a backside fin isolation structure. In some examples, the fin isolation structure includes any suitable low-k dielectric material, such as silicon dioxide. According to some embodiments, the dielectric material of the fin isolation structure is deposited using a conformal deposition technique, such as CVD, PECVD, or ALD, to name a few examples. Accordingly, the dielectric material forms conformally on the exposed surfaces and increases in thickness as the deposition process continues. Ultimately, the deposited dielectric material comes together near the center of the structure, forming a seam at the interface where the material contacts itself. According to some embodiments, the seam extends from the bottom surface of the fin isolation structure towards the top surface of the fin isolation structure without reaching the top surface. According to some embodiments, the fin isolation structure exhibits a tapering width having a top surface with a first width that is at least 3 nm, at least 5 nm, at least 7 nm, or at least 10 nm shorter than a second width at a bottom surface of the fin isolation structure.

### Example System

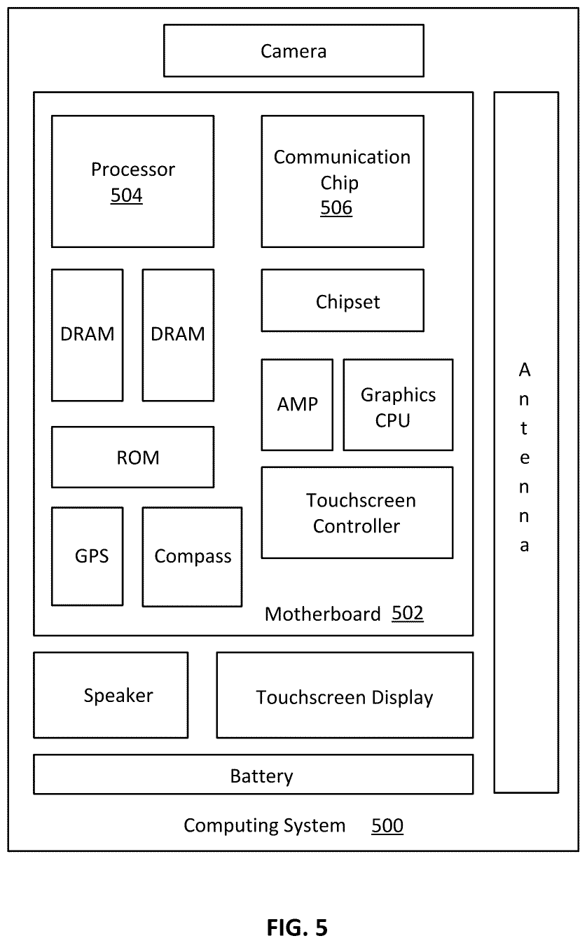

FIG. 5 is an example computing system implemented with one or more of the integrated circuit structures as disclosed herein, in accordance with some embodiments of the present disclosure. As can be seen, the computing system 500 houses a motherboard 502. The motherboard 502 may include a number of components, including, but not limited to, a processor 504 and at least one communication chip 506, each of which can be physically and electrically coupled to the motherboard 502, or otherwise integrated therein. As will be appreciated, the motherboard 502 may be, for example, any printed circuit board (PCB), whether a main board, a daughterboard mounted on a main board, or the only board of system 500, etc.

Depending on its applications, computing system 500 may include one or more other components that may or may not be physically and electrically coupled to the motherboard 502. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 500 may include one or more integrated circuit structures or devices configured in accordance with an example embodiment (e.g., a module including an integrated circuit configured with backside-formed fin isolation structures between semiconductor devices, as variously provided herein). In some embodiments, multiple functions can be integrated into one or more chips (e.g., for instance, note that the communication chip 506 can be part of or otherwise integrated into the processor 504).

The communication chip 506 enables wireless communications for the transfer of data to and from the computing system 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing system 500 includes an integrated circuit die packaged within the processor 504. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 506 also may include an integrated circuit die packaged within the communication chip 506. In accordance with some such example embodiments, the integrated circuit die of the communication chip includes one or more semiconductor devices as variously described herein. As will be appreciated in light of this disclosure, note that multi-standard wireless capability may be integrated directly into the processor 504 (e.g., where functionality of any chips 506 is integrated into processor 504, rather than having separate communication chips). Further note that processor 504 may be a chip set having such wireless capability. In short, any number of processor 504 and/or communication chips 506 can be used. Likewise, any one chip or chip set can have multiple functions integrated therein.

In various implementations, the computing system 500 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 500 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device having a first semiconductor region extending in a first direction from a first source or drain region and a first gate structure extending in a second direction over the first semiconductor region, a second semiconductor device having a second semiconductor region extending in the first direction from a second source or drain region and a second gate structure extending in the second direction over the second semiconductor region, and a dielectric structure extending in the second direction between the first source or drain region and the second source or drain region and extending in a third direction along an entire height of the first source or drain region and the second source or drain region. The second semiconductor region is aligned with the first semiconductor region along the first direction. The dielectric structure has a first width along the first direction across a top surface of the dielectric structure and a second width along the first direction across a bottom surface of the dielectric structure. The first width is less than the second width. The bottom surface of the dielectric structure is below a bottom of the first gate structure and below a bottom of the second gate structure.

Example 2 includes the integrated circuit of Example 1, wherein the dielectric structure comprises a low-k dielectric material.

Example 3 includes the integrated circuit of Example 2, wherein the dielectric structure comprises silicon and oxygen.

Example 4 includes the integrated circuit of any one of Examples 1-3, further comprising an etch stop layer on a top surface of the dielectric structure.

Example 5 includes the integrated circuit of Example 4, wherein the etch stop layer comprises aluminum and oxygen, silicon and carbon, or silicon and nitrogen.

Example 6 includes the integrated circuit of any one of Examples 1-5, wherein the dielectric structure comprises a seam through a central portion of the dielectric structure and extending from the bottom surface of the dielectric structure towards the top surface of the dielectric structure.

Example 7 includes the integrated circuit of any one of Examples 1-6, wherein the first source or drain region is an n-type region and the second source or drain region is a p-type region.

Example 8 includes the integrated circuit of any one of Examples 1-7, wherein the first semiconductor region comprises a plurality of first semiconductor nanoribbons and the second semiconductor region comprises a plurality of second semiconductor nanoribbons.

Example 9 includes the integrated circuit of Example 8, wherein the plurality of first semiconductor nanoribbons and the plurality of second semiconductor nanoribbons comprise germanium, silicon, or a combination thereof.

Example 10 includes the integrated circuit of any one of Examples 1-9, further comprising a third semiconductor region extending between the dielectric structure and the first source or drain region along the first direction and a fourth semiconductor region extending between the dielectric structure and the second source or drain region along the first direction.

Example 11 includes the integrated circuit of Example 10, wherein the third and fourth semiconductor regions are aligned with the first and second semiconductor regions along the first direction.

Example 12 includes the integrated circuit of any one of Examples 1-11, wherein the first width is at least 5 nm less than the second width.

Example 13 is a die that includes the integrated circuit of any one of Examples 1-12.

Example 14 is an electronic device that includes a chip package having one or more dies. At least one of the one or more dies includes a first plurality of semiconductor nanoribbons extending in a first direction from a first source or drain region, a second plurality of semiconductor nanoribbons extending in the first direction from a second source or drain region with the second plurality of semiconductor nanoribbons being aligned with the first plurality of semiconductor nanoribbons along the first direction, a first gate structure extending in a second direction of the first plurality of semiconductor nanoribbons, a second gate structure extending in the second direction of the second plurality of semiconductor nanoribbons, and a dielectric structure extending in the second direction between the first source or drain region and the second source or drain region and extending in a third direction along at least an entire height of the first source or drain region and the second source or drain region. The dielectric structure has tapered sidewalls such that a top surface of the dielectric structure has a first width along the first direction and a bottom surface of the dielectric structure has a second width along the first direction with the first width being less than the second width.

Example 15 includes the electronic device of Example 14, wherein the dielectric structure comprises a low-k dielectric material.

Example 16 includes the electronic device of Example 15, wherein the dielectric structure comprises silicon and oxygen.

Example 17 includes the electronic device of any one of Examples 14-16, wherein the at least one of the one or more dies further comprises an etch stop layer on a top surface of the dielectric structure.

Example 18 includes the electronic device of Example 17, wherein the etch stop layer comprises aluminum and oxygen, silicon and carbon, or silicon and nitrogen.

Example 19 includes the electronic device of any one of Examples 14-18, wherein the dielectric structure comprises a seam through a central portion of the dielectric structure and extending from the bottom surface of the dielectric structure towards the top surface of the dielectric structure.

Example 20 includes the electronic device of any one of Examples 14-19, wherein the first source or drain region is an n-type region and the second source or drain region is a p-type region.

Example 21 includes the electronic device of any one of Examples 14-20, wherein the first plurality of semiconductor nanoribbons and the second plurality of semiconductor nanoribbons comprise germanium, silicon, or a combination thereof.

Example 22 includes the electronic device of any one of Examples 14-21, further comprising a third plurality of semiconductor nanoribbons extending between the dielectric structure and the first source or drain region along the first direction and a fourth plurality of semiconductor nanoribbons extending between the dielectric structure and the second source or drain region along the first direction.

Example 23 includes the electronic device of Example 22, wherein the third and fourth plurality of semiconductor nanoribbons are aligned with the first and second plurality of semiconductor nanoribbons along the first direction.

Example 24 includes the electronic device of any one of Examples 14-23, wherein the first width is at least 5 nm less than the second width.

Example 25 includes the electronic device of any one of Examples 14-24, further comprising a printed circuit board, wherein the chip package is coupled to the printed circuit board.

Example 26 is a method of forming an integrated circuit. The method includes: forming a fin comprising semiconductor material, the fin extending above a substrate and extending lengthwise along a first direction; forming a first dielectric layer around a base portion of the fin; forming source or drain regions at ends of the fin; forming a gate structure over the semiconductor material of the fin in a second direction different from the first direction; removing at least a portion of the substrate from a backside of the integrated circuit; etching a trench recess from the backside through at least an entire height of the gate structure; and filling the trench recess with a dielectric material.

Example 27 includes the method of Example 26, wherein filling the trench recess comprises depositing a low-k dielectric material using chemical vapor deposition (CVD).

Example 28 includes the method of Example 26 or 27, further comprising forming an etch stop layer over the gate structure.

Example 29 includes the method of Example 28, wherein etching the trench recess comprises etching the trench recess from the backside until the etch stop layer is reached.

Example 30 includes the method of any one of Examples 26-29, wherein etching the trench recess comprises etching the trench recess through a metal material of the gate structure and through the semiconductor material of the fin.

Example 31 is an integrated circuit that includes a first semiconductor region extending in a first direction from a first source or drain region, a second semiconductor region extending in the first direction from a second source or drain region, a dielectric structure extending in a second direction between the first semiconductor region and the second semiconductor region and extending in a third direction along at least an entire height of the first source or drain region and the second source or drain region. The dielectric structure has tapered sidewalls such that a top surface of the dielectric structure has a first width along the first direction, and a bottom surface of the dielectric structure has a second width along the first direction with the first width being less than the second width. The second semiconductor region is aligned with the first semiconductor region along the first direction.

Example 32 includes the integrated circuit of Example 31, wherein the dielectric structure directly contacts the first semiconductor region and the second semiconductor region.

Example 33 includes the integrated circuit of Example 31 or 32, wherein the dielectric structure comprises a low-k dielectric material.

Example 34 includes the integrated circuit of Example 33, wherein the dielectric structure comprises silicon and oxygen.

Example 35 includes the integrated circuit of any one of Examples 31-34, further comprising an etch stop layer on the top surface of the dielectric structure.

Example 36 includes the integrated circuit of Example 35, wherein the etch stop layer comprises aluminum and oxygen, silicon and carbon, or silicon and nitrogen.

Example 37 includes the integrated circuit of any one of Examples 31-36, wherein the dielectric structure comprises a seam through a central portion of the dielectric structure and extending from the bottom surface of the dielectric structure towards the top surface of the dielectric structure.

Example 38 includes the integrated circuit of any one of Examples 31-37, wherein the first source or drain region is an n-type region and the second source or drain region is a p-type region.

Example 39 includes the integrated circuit of any one of Examples 31-38, wherein the first semiconductor region comprises a plurality of first semiconductor nanoribbons and the second semiconductor region comprises a plurality of second semiconductor nanoribbons.

Example 40 includes the integrated circuit of Example 39, wherein the plurality of first semiconductor nanoribbons and the plurality of second semiconductor nanoribbons comprise germanium, silicon, or a combination thereof.

Example 41 includes the integrated circuit of any one of Examples 31-40, wherein the second direction is orthogonal to the first direction.

Example 42 includes the integrated circuit of any one of Examples 31-41, wherein the first width is at least 5 nm less than the second width.

Example 43 is a die that includes the integrated circuit of any one of Examples 31-42.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending in a first direction from a first source or drain region, and a first gate structure extending in a second direction over the first semiconductor region;
a second semiconductor device having a second semiconductor region extending in the first direction from a second source or drain region, and a second gate structure extending in the second direction over the second semiconductor region, wherein the second semiconductor region is aligned with the first semiconductor region along the first direction; and
a dielectric structure extending in the second direction between the first source or drain region and the second source or drain region, and extending in a third direction along at least an entire height of the first source or drain region and the second source or drain region,
wherein the dielectric structure has a first width along the first direction across a top surface of the dielectric structure and a second width along the first direction across a bottom surface of the dielectric structure, the first width being less than the second width, the bottom surface of the dielectric structure being below a bottom of the first gate structure and below a bottom of the second gate structure.

2. The integrated circuit of claim 1, wherein the dielectric structure comprises a low-k dielectric material.

3. The integrated circuit of claim 1, further comprising an etch stop layer on a top surface of the dielectric structure.

4. The integrated circuit of claim 3, wherein the etch stop layer comprises aluminum and oxygen, silicon and carbon, or silicon and nitrogen.

5. The integrated circuit of claim 1, wherein the dielectric structure comprises a seam through a central portion of the dielectric structure and extending from the bottom surface of the dielectric structure towards the top surface of the dielectric structure.

6. The integrated circuit of claim 1, wherein the first source or drain region is an n-type region and the second source or drain region is a p-type region.

7. The integrated circuit of claim 1, further comprising a third semiconductor region extending between the dielectric structure and the first source or drain region along the first direction and a fourth semiconductor region extending between the dielectric structure and the second source or drain region along the first direction.

8. The integrated circuit of claim 7, wherein the third and fourth semiconductor regions are aligned with the first and second semiconductor regions along the first direction.

9. The integrated circuit of claim 1, wherein the first width is at least 5 nm less than the second width.

10. An electronic device, comprising:
a chip package comprising one or more dies, at least one of the one or more dies comprising
a first plurality of semiconductor nanoribbons extending in a first direction from a first source or drain region;
a second plurality of semiconductor nanoribbons extending in the first direction from a second source or drain region, wherein the second plurality of semiconductor nanoribbons is aligned with the first plurality of semiconductor nanoribbons along the first direction;
a first gate structure extending in a second direction of the first plurality of semiconductor nanoribbons;
a second gate structure extending in the second direction of the second plurality of semiconductor nanoribbons; and
a dielectric structure extending in the second direction between the first source or drain region and the second source or drain region and extending in a third direction along at least an entire height of the first source or drain region and the second source or drain region,
wherein the dielectric structure has tapered sidewalls such that a top surface of the dielectric structure has a first width along the first direction, and a bottom surface of the dielectric structure has a second width along the first direction, the first width being less than the second width.

11. The electronic device of claim 10, wherein the dielectric structure comprises a low-k dielectric material.

12. The electronic device of claim 10, wherein the at least one of the one or more dies further comprises an etch stop layer on a top surface of the dielectric structure.

13. The electronic device of claim 10, wherein the dielectric structure comprises a seam through a central portion of the dielectric structure and extending from the bottom surface of the dielectric structure towards the top surface of the dielectric structure.

14. The electronic device of claim 10, wherein the first width is at least 5 nm less than the second width.

15. An integrated circuit comprising:
a first semiconductor region extending in a first direction from a first source or drain region;
a second semiconductor region extending in the first direction from a second source or drain region, wherein the second semiconductor region is aligned with the first semiconductor region along the first direction; and
a dielectric structure extending in a second direction between the first semiconductor region and the second semiconductor region and extending in a third direction along at least an entire height of the first source or drain region and the second source or drain region,
wherein the dielectric structure has tapered sidewalls such that a top surface of the dielectric structure has a first width along the first direction, and a bottom surface of the dielectric structure has a second width along the first direction, the first width being less than the second width.

16. The integrated circuit of claim 15, wherein the dielectric structure directly contacts the first semiconductor region and the second semiconductor region.

17. The integrated circuit of claim 15, wherein the dielectric structure comprises a low-k dielectric material.

18. The integrated circuit of claim 15, wherein the dielectric structure comprises a seam through a central portion of the dielectric structure and extending from the bottom surface of the dielectric structure towards the top surface of the dielectric structure.

19. The integrated circuit of claim 15, wherein the first source or drain region is an n-type region and the second source or drain region is a p-type region.

20. The integrated circuit of claim 15, wherein the first width is at least 5 nm less than the second width.
